(19) United States
(12) Patent Application Publication
(10) Pub. No.: US 2026/0160801 A1
(43) Pub. Date: Jun. 11, 2026

(54) Enhanced Scan Test Learning

(71) Applicant: QUALCOMM Incorporated, San Diego, CA (US)

(72) Inventor: Szu Huat GOH, Singapore (SG)

(21) Appl. No.: 18/972,648

(22) Filed: Dec. 6, 2024

(51) Int. Cl. G01R 31/28

(52) U.S. Cl. CPC G01R 31/2834

(57) ABSTRACT

A scan test fault analysis system is provided that selects a plurality of features from scan diagnosis report for a faulty die and processes the plurality of features through a trained artificial neural network to provide a predicted location of a fault in the faulty die.

### TECHNICAL FIELD

This application relates to integrated circuit testing, and more particularly to an enhanced scan test learning system and method for integrated circuits.

### BACKGROUND

Automated test equipment (ATE) detects whether an integrated circuit (the device under test (DUT)) performs correctly or has a fault. In an ATE scan test, the automatic test equipment shifts test patterns into the DUT to identify whether the DUT's logic paths are faulty. Based upon the scan test, a scan diagnosis may be performed to attempt to identify what is the cause of a failure. However, the scan diagnosis is typically ambiguous in that it may point to multiple potential causes of the fault. The scan diagnosis may then be confirmed or refuted through a physical fault analysis (PFA) of the DUT such as through scanning electron microscopy or other techniques.

The ambiguity of the scan diagnosis raises an issue in that physical fault analysis may require sectioning the DUT. Since it is unknown exactly where the defect will be, the DUT is typically sectioned and analyzed layer by layer. The resulting analysis is time consuming and expensive. Should a specific layer be targeted instead of a layer-by-layer analysis, the fault may be missed. For example, if the fault is believed to be a front end of line (FEOL) fault, the various metal layers may be ground off to expose the patterned semiconductor die features. Should the fault instead be in one of the metal layers, the PFA then cannot identify the actual cause of the fault because the faulty metal layers were ground away. It is thus critical that the ambiguity in the scan diagnosis be reduced so that a subsequent physical fault analysis may properly identify the fault in a timely fashion.

### SUMMARY

In accordance with an aspect of the disclosure, a scan test fault analysis method is provided that includes the acts of: selecting a plurality of features from a scan diagnosis report for a faulty die; and processing the plurality of features through an artificial neural network to provide a predicted location of a fault in the faulty die.

In accordance with another aspect of the disclosure, a scan test fault analysis system is provided that includes at least one processor configured to: select a plurality of features from a scan diagnosis report for a faulty die; implement an artificial neural network; and process the plurality of features through the artificial neural network to provide a predicted location of a fault in the faulty die.

In accordance with yet another aspect of the disclosure, a scan test fault analysis method is provided that includes: providing a plurality of faulty first dies, wherein each faulty first die in the plurality of faulty first dies has a known fault location; performing a scan test on each faulty first die to provide a first scan diagnosis report for each faulty die; selecting a plurality of features from each first scan diagnosis report to provide a selected first plurality of features for each faulty first die; processing each selected first plurality of features through an artificial neural network to provide a predicted location of a fault in each faulty first die; and training the artificial neural network to improve an accuracy of the predicated location based upon each faulty first die's known fault location to provide a trained artificial neural network.

These and other advantageous features may be better appreciated through the following detailed description.

### BRIEF DESCRIPTION OF THE DRAWINGS

FIG. 1 illustrates the suspect locations in an example integrated circuit cross section for a scan test fault analysis in accordance with an aspect of the disclosure.

FIG. 2 illustrates an example artificial neural network for a scan test analysis system in accordance with an aspect of the disclosure.

FIG. 3 is a flowchart for an example method of training artificial neural networks for a scan test analysis system in accordance with an aspect of the disclosure.

FIG. 4 is a flowchart for an example method of using trained and validated artificial neural networks for a scan test analysis in accordance with an aspect of the disclosure.

FIG. 5 illustrates an example scan test analysis system in accordance with an aspect of the disclosure.

FIG. 6 is a flowchart for a method of performing a scan test analysis using an artificial neural network in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

As known in the automatic test pattern generation (ATPG) scan test arts, a diagnosis tool analyzes the results the results of scan testing a DUT through automatic test equipment to provide a scan diagnosis report that identifies potential failure suspects. For example, the diagnosis tool may use the input test patterns, the output test datalog from the scan testing, and design netlist information to identify potential failure suspects (also denoted as diagnosis suspects). One diagnosis suspect may be a fault in the front end of line layer for the integrated circuit or die. Similarly, another diagnosis suspect may be a fault in one of the metal layers. The diagnosis tool may thus generate a scan diagnosis report that provides information on each diagnosis suspect along with failing cells and interconnects associated with the diagnosis suspect and the suspected failure mode such as an open circuit, a bridge, or a dominant bridge with a confidence score.

The scan diagnosis report may then guide a subsequent physical fault analysis of the failed circuit. Since a physical fault analysis must typically destroy portions of the failed integrated circuit to expose a suspect layer, it is imperative that the scan diagnosis accurately identify the diagnosis suspect. However, conventional techniques to improve the fault localization from scan diagnoses suffer from a number of problems. For example, layout-aware scan diagnosis integrates a physical design database during the diagnostic process. But despite the use of the physical design database such as a graphic design system (GDS) database, there is inherent ambiguity in that various diagnostic callout nets may contain the fault. Should a fault be in, for example, the second metal layer, the remaining candidates such as one of the other metal layers or the front end of line function as “noise” with respect to the true location of the fault.

To improve the fault localization of the scan diagnosis, it is known to use the scan diagnosis reports from numerous (e.g., 100 to 200) faulty DUTs. But leveraging such a volume diagnosis requires an analysis to concentrate on the most likely systematic failure. In addition, the accuracy of prediction with volume analysis is dependent on the sample size and whether the faults are random or correlated. Due to the occurrence of random faults, a value diagnosis must still consider multiple diagnosis suspects, thus resulting in little benefit with respect to localizing the fault and narrowing down the defect search area for a subsequent physical failure analysis.

To address these problems with existing scan diagnoses, an enhanced scan test learning “bottom-up” approach is disclosed herein that solves the problems associated with traditional volume diagnosis. In this bottom-up approach, an artificial neural network (ANN) is trained on the scan diagnosis reports of scan-tested failed die that also had their faults verified through a physical fault analysis. The ANN is trained to predict the fault location (e.g., front end of the line) from the scan diagnosis reports so that the prediction matches the actual fault that was verified through the physical fault analysis. The trained ANN may then be used to process the scan diagnosis reports from the scan testing of a new faulty die to predict where the fault lies. As will be explained further herein, the resulting prediction is advantageously accurate (e.g., an accuracy of 95% or better) such that a physical fault analysis may be better directed to confirm whether the true fault is as predicted.

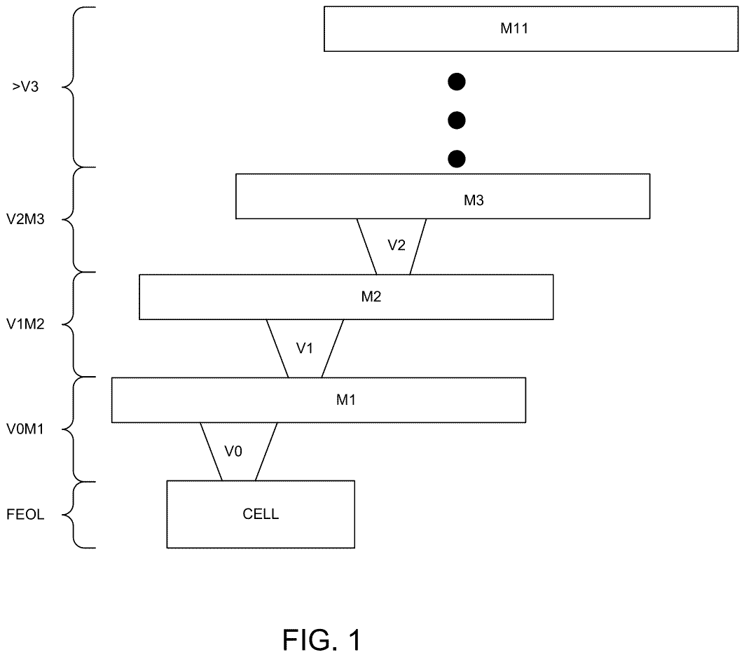

Before the enhanced scan test learning is discussed in more detail, some scan testing concepts will first be discussed. During a scan test, the ATE may compare an output scan test vector (e.g., a binary series of ones and zeroes) to the expected output scan test vector. Should one or more bits in the output vector differ from the expected result, the die is faulty. But note that the output vector passed through a net of various transistors, vias, and metal layers in the integrated circuit. For example, consider the cross-sectional view of an integrated circuit 100 shown in FIG. 1. The device level (doped semiconductor level) is designated as the front end of line (FEOL). From the device level, a plurality of zeroth vias form a zeroth via layer (V0) that extends to an initial patterned metal layer M1 (for illustration clarity, the various via levels in FIG. 1 are represented by just one via each). From the metal layer M1, a plurality of first vias form a first via layer (V1) that extends to a patterned second metal layer M2. Similarly, a plurality of second vias form a second via layer (V2) that extends from the second metal layer M2 to a patterned third metal layer M3. This pattern of a via layer and an adjacent metal layer continues from the third metal layer M3 but for illustration brevity is represented only by a final patterned eleventh metal layer M11. With regard to localizing a fault, a processing of a diagnosis report from a diagnosis tool that performs the scan diagnosis on the results of the output scan test vectors from the scan testing by an ATE may concatenate a via and the adjacent metal layer. Some examples in the following discussion will thus be directed to the processing of a diagnosis report in which the suspected location of a fault (designated herein as a suspect or a fault suspect) is aggregated with respect to both a via layer and the adjacent metal layer. For example, the zeroth via layer V0 and the first metal layer M1 form a suspect V0M1. Similarly, the first via layer V1 and the second metal layer M2 form a suspect V1M2. In the same fashion, the second via layer V2 and the third metal layer M3 form a suspect V2M3. The via layers and metal layers above the third metal layer M3 are designated collectively as a “>V3” fault suspect since the fault in such a suspect will either be in the third via layer V3 (not illustrated) that extends from the third metal layer 3 to a fourth metal layer M4 (not illustrated) or be in the fourth metal layer M4 or in some higher via layer or metal layer. Finally, the FEOL forms another suspect. There are thus five candidates for suspects shown in FIG. 1, but it will be appreciated that the exact number of candidates for suspects depends upon a number of factors including the ATE and the diagnosis tool. It will be appreciated, however, that the enhanced fault diagnosis disclosed herein may instead identify individual layers or sub-layers as the suspects.

For a given fault, the diagnosis tool may identify a symptom of the fault such as a suspected open circuit or a bridge fault. For each symptom, the diagnosis tool may identify various suspects such as chosen from the candidates identified in FIG. 1. Given these underlying concepts, the machine learning disclosed herein will now be discussed in more detail. The machine learning involves the training of an ANN. As known in the ANN arts, an ANN includes an input layer, one or more hidden layers, and an output layer. The input layer for the ANN includes a node for each feature selected from the diagnosis scan report for a failed die in a training database. The features in the following Table 1 are exemplary and may be varied depending upon the ATE and the corresponding diagnosis tool:

TABLE 1

| Features | |
|---|---|
| Index | Description |
| f₁ | Total Symptoms |
| f₂ | Total Suspect |
| f₃ | Highest suspect score |
| . . . | Fault type, model, suspect |
| | layer, sub-layer, . . . |

A first feature f₁ may correspond to the total number of symptoms in the diagnosis scan report. As known in the automatic test pattern generation (ATPG) fault analysis arts such as performed by the diagnosis tool, a symptom refers to the outcome or result of a fault in the DUT on the circuit output (the output test scan vector). For example, a stuck-at fault in the DUT may result in a symptom being that the output scan test vector maintains a static binary logic state (0 or 1) during a period in which the output scan test vector should change. The symptom is thus the manifestation or effect of the specific fault in the DUT. A second feature f₂ may correspond to the total number of suspects in the diagnosis scan report. A third feature f₃ may correspond to the highest suspect score as defined by the diagnosis tool. A variety of additional features is possible such as the fault type, the fault model, the suspect layer, the suspect sub-layer (for example, a defect in V1M2 actually being in the first via layer V1 and not in the second metal layer M2), and so on. Since each ANN may have potential biases in predicting the fault localization (identifying which of the possible candidate suspects as discussed with regard to FIG. 1 contains the actual fault), it may be beneficial to train multiple ANNs, with each ANN including a unique subset of the features in its input layer. To distinguish between the ANNs, each ANN having a unique input layer of features may be denoted as an ANN model. It is arbitrary how many ANN models are used but in one example implementation, five ANN models were trained.

It is also arbitrary how many hidden layers may be used for each ANN and the corresponding number of nodes for each hidden layer but in the following discussion it will be assumed that one hidden layer having sixty nodes is used. The output layer for each ANN model aggregates the contribution from the hidden nodes and applies a suitable function such as a softmax function to determine the probability of each suspect (which may be designated as a class with respect to the ANN model output). The output layer for an example ANN model may identify only one suspect or instead identify multiple suspects such as to provide a first probability for the fault being in the FEOL, a second probability for the fault being in the V0M1, and so on. More generally, an ANN model gives the probability of a variety of suspects for the fault location. The probabilities from the ANN models are then aggregated to get the output probabilities for the suspects as containing the fault location. The suspect having the highest aggregated probability then guides a subsequent physical fault analysis on the faulty circuit.

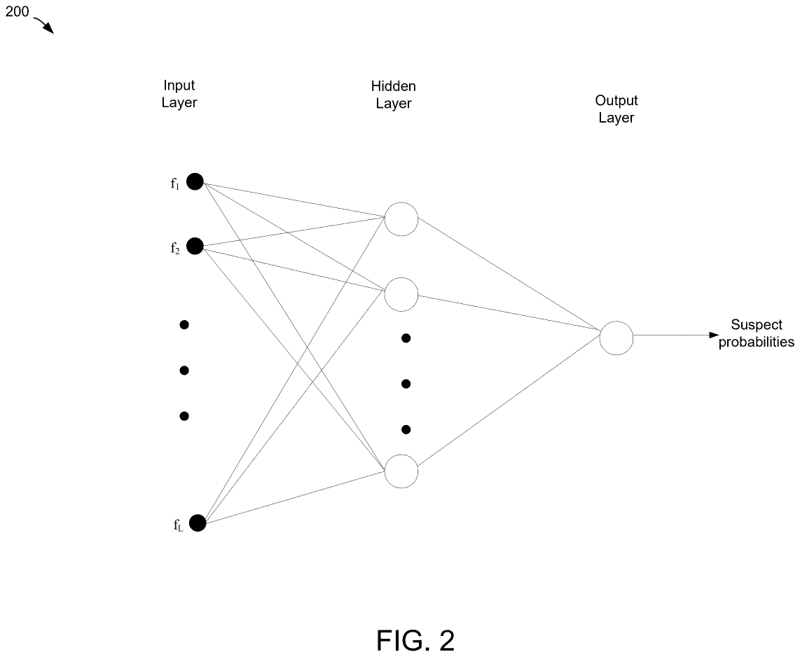

An example ANN model 200 is shown in FIG. 2. There are L nodes in the input layer, where L is a plural positive integer. Each node corresponds to a given feature. A first node thus corresponds to the first feature f₁, a second node corresponds to the second feature f₂, and so on such that an Lth node corresponds to an Lth feature f_{L}. Each node in the hidden layer applies an activation function to its input node values as weighted by corresponding weight factors and also biased by a bias (not illustrated). In one implementation, the activation function may be a hyperbolic tangent activation function. The output from each node in the hidden layer may then be determined from the following Equation 1:

$${u}_{j , j ∈ [ 1 : M ]} = tanh {\sum }_{i = 1}^{L} {a}_{j} + {wt}_{ij} {f}_{i} \qquad Eq . ( 1 )$$

where uⱼ is the hidden node output for a jth hidden node, aⱼ is the bias for the jth hidden node, wtᵢⱼ is the weight for the ith input to the jth hidden node, and fᵢ is the feature input from the ith node in the input layer. The output layer aggregates the contributions from the hidden layer nodes according to their weighting factors and also as biased by a bias (not illustrated). A suitable function as a softmax function is applied to the aggregation results to determine a probability of each suspect (e.g., a first probability that the fault lies in the FEOL, a second probability that the fault lies in the V0M1, and so on). The resulting probabilities from the various ANN models may then be summed to provide the final probabilities of the suspects.

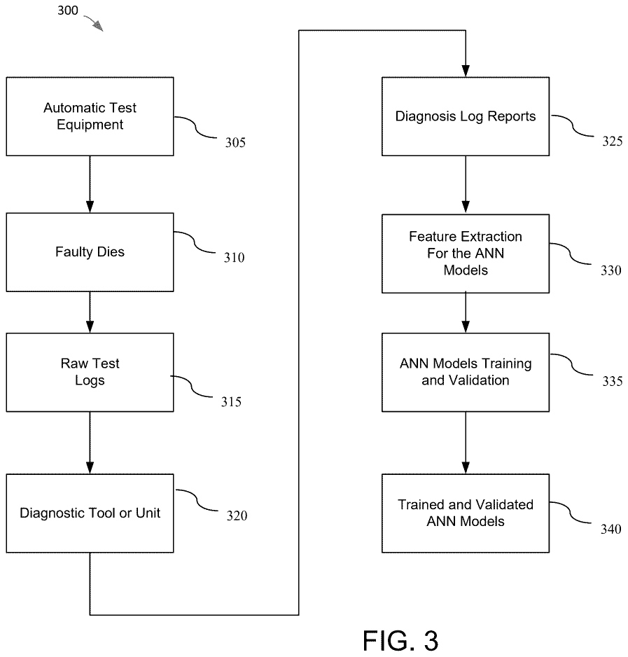

An example ANN training method is summarized in FIG. 3. An ATE 305 performs a scan test on a plurality of training and validation faulty dies (each being a device under test) 310. The fault location for the training and validation faulty dies 310 is verified through corresponding physical fault analyses. From the scan tests, the ATE 305 prepares a plurality of raw test logs 315. A diagnostic tool 320 (which may also be denoted as a diagnostic unit) prepares a plurality of diagnosis log reports 325 that identify the symptom(s) and corresponding suspect(s) for the training and validation faulty dies 310. The features for each ANN model are then extracted from the diagnosis log reports 325 in an extraction step 330 so that the ANN models may be trained and validated in a step 335 based upon the known fault location of the training and validation faulty dies 310 to produce the finished ANN models 340 that may then be used to identify the suspect holding the actual defect (e.g., the FEOL, V0M1, and so on) with an acceptable accuracy as compared to the actual location of the defect as determined through a physical fault analysis.

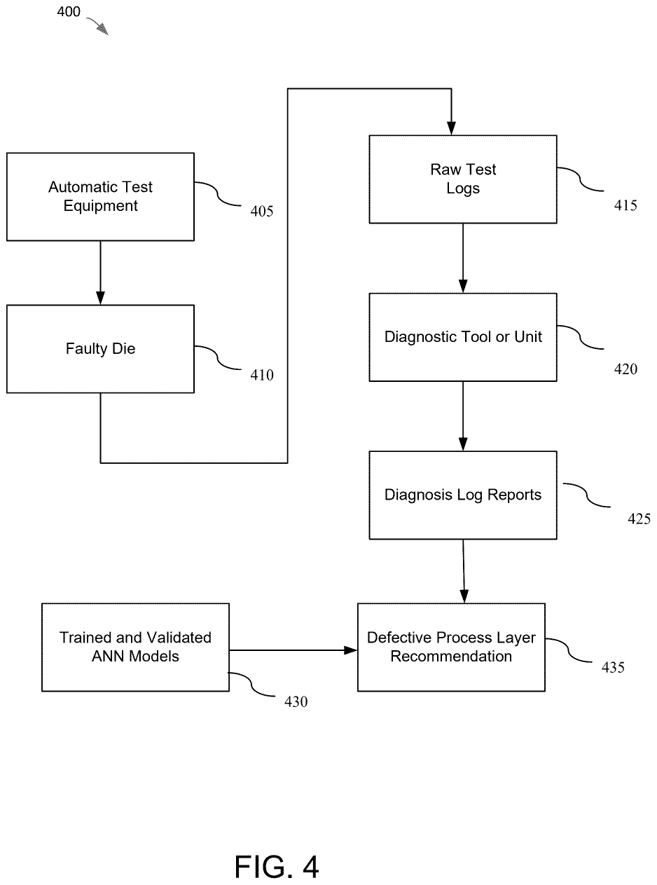

With the ANN models trained and validated, the ANN models may then be used to identify the suspect in faulty dies that have not yet been subjected to a physical fault analysis. In this fashion, the ensuing physical fault analysis may focus on the identified suspect and more accurately and quickly identify the actual fault location. A flowchart 400 for the application of the ANN models is shown in FIG. 4. An automatic test equipment 405 performs a scan test on a faulty die 410 to provide at least one raw test log 415 that is processed by a diagnosis tool 420 to provide at least one diagnosis log report 425. A suitable processor (or processors) extracts the appropriate features from the log report 425 and processes the extracted features through the trained ANN models 430 to provide a defective process layer recommendation 435 (an identification of a suspect such as the FEOL, the V0M1, and so on) that contains the actual defect).

To test the accuracy of the resulting recommendation, the trained ANN models may be applied on the log diagnosis report(s) from a faulty die in which the fault location is already known. For example, two different ANN models may be used, with the application of the ANN models on the log diagnosis report(s) repeated such as five separate times. Since the fault location is already known, it is expected that each ANN model identifies it accordingly. But the features chosen for each ANN model may affect the likelihood as to which process layer is recommended. For example, it may be that one ANN model excels in accurately predicting that the FEOL or >V3 contains the actual fault whereas another ANN model excels in accurately predicting that V2M2 contains the fault. It may thus be appreciated that using different ANN models (each having its own unique selection of features for its input layer) and then aggregating the predictions from the ANN models to provide an overall prediction is advantageous in increasing the accuracy of the prediction.

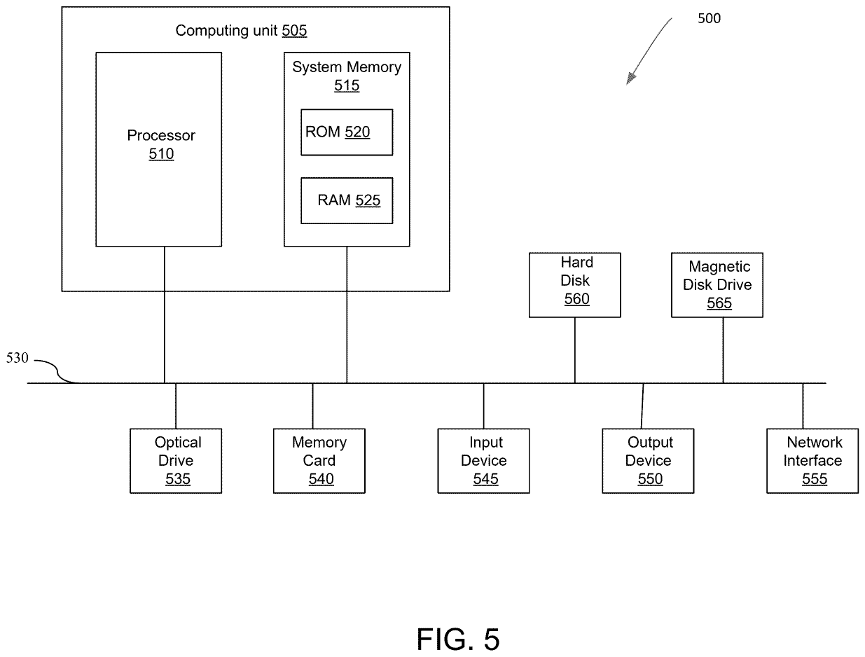

Any suitable computing system may be used to implement a scan test analysis system for performing the ANN models. An example scan test fault analysis system 500 that may be programmed to implement the ANN models is shown in FIG. 5. As seen in this figure, the system 500 includes a computing unit 505 with an at least one processor 510 that executes instructions from and stores data in a system memory 515. The at least one processor 510 may be any type of programmable electronic device for executing software instructions but will typically be one or more microprocessors. The system memory 515 may include both a read-only memory (ROM) 520 and a random-access memory (RAM) 525. As will be appreciated by those of ordinary skill in the art, both the read-only memory (ROM) 520 and the random-access memory (RAM) 525 may store software instructions for execution by the at least one processor 510.

The at least one processor 510 and the system memory 515 are connected, either directly or indirectly, through a bus 530 or alternate communication structure, to one or more peripheral devices. For example, the at least one processor 510 or the system memory 515 may be directly or indirectly connected to one or more additional memory storage devices, such as a “hard” magnetic disk drive 560, a removable magnetic disk drive 565, an optical disk drive 535, or a flash memory card 540. The at least one processor 510 and the system memory 515 also may be directly or indirectly connected to one or more input devices 545 and one or more output devices 550. The input devices 545 may include, for example, a keyboard, a pointing device (such as a mouse, touchpad, stylus, trackball, or joystick), a scanner, a camera, and a microphone. The output devices 545 may include, for example, a monitor display, a printer and speakers. With various examples of the scan test fault analysis system 500, one or more of the peripheral devices 535, 540, 545, 560, and 565 may be internally housed within a housing of the system 500. Alternately, one or more of the peripheral devices 535, 540, 545, 560, and 565 may be external to the housing and connected to the bus 530 through, for example, a Universal Serial Bus (USB) connection.

With some implementations, the scan test fault analysis system 500 may be directly or indirectly connected to one or more network interfaces 555 for communicating with other devices making up a network. The network interface 555 translates data and control signals from the system 500 into network messages according to one or more communication protocols, such as the transmission control protocol (TCP) and the Internet protocol (IP). Also, the interface 555 may employ any suitable connection agent (or combination of agents) for connecting to a network, including, for example, a wireless transceiver, a modem, or an Ethernet connection. Such network interfaces and protocols are well known in the art, and thus will not be discussed here in more detail. It should be appreciated that the system 500 is illustrated as an example only, and it not intended to be limiting. Various implementations may be formed using one or more scan test analysis systems that include the components of the system 500 illustrated in FIG. 1, or which include only a subset of the components illustrated in FIG. 5, or which include an alternate combination of components, including components that are not shown in FIG. 5.

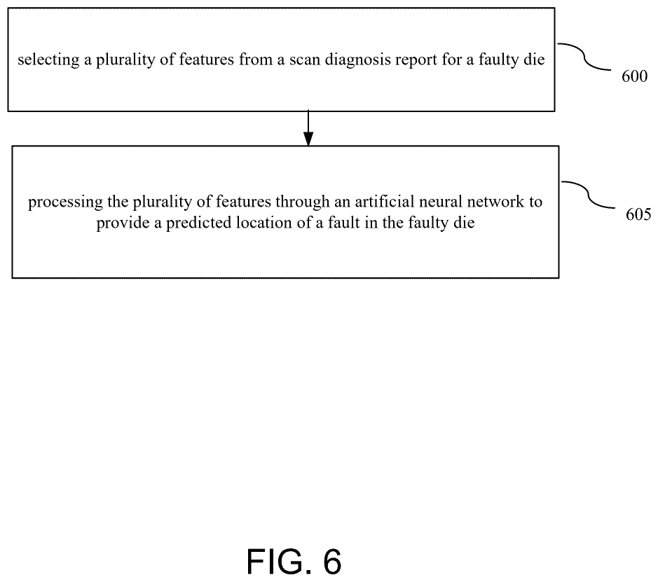

An example scan test fault analysis method will now be summarized with respect to the flowchart of FIG. 6. The method includes an act 600 of selecting a plurality of features from a scan diagnosis report for a faulty die. The selection of features discussed with respect to Table 1 is an example of act 600. The method further includes an act 605 of processing the plurality of features through an artificial neural network to provide a predicted location of a fault in the faulty die. The processing of the selected features using the trained and validated ANN models 430 as discussed with respect to the flowchart 400 is an example of act 605.

The disclosure will now be summarized in the following series of clauses:

Clause 1. A scan test fault analysis method, comprising:
selecting a plurality of features from a scan diagnosis report for a faulty die; and
processing the plurality of features through an artificial neural network to provide a predicted location of a fault in the faulty die.

Clause 2. The scan test fault analysis method of clause 1, wherein selecting the plurality of features comprises selecting a first plurality of features for a first artificial neural network and selecting a second plurality of features for a second artificial neural network, and wherein processing the plurality of features through the artificial neural network comprises processing the first plurality of features through the first artificial neural network and processing the second plurality of features through the second artificial neural network.

Clause 3. The scan test fault analysis method of clause 2, further comprising:
averaging a first prediction from the first artificial neural network with a second prediction from the second artificial neural network to provide the predicted location of the fault in the faulty die.

Clause 4. The scan test fault analysis method of any of clauses 1-3, further comprising:
performing a scan test on the faulty die using an automatic test equipment to provide a scan test result; and
processing the scan test result in a diagnosis tool to provide the scan diagnosis report.

Clause 5. The scan test fault analysis method of clause 4, wherein the plurality of features includes a total number of symptoms of the fault from the scan diagnosis report.

Clause 6. The scan test fault analysis method of clause 4, wherein the plurality of features includes at least one feature selected from a group consisting of a total number of suspects for a location of the fault, a fault type, and a suspect layer for the location of the fault.

Clause 7. The scan test fault analysis method of any of clauses 1-6, further comprising:
directing a physical fault analysis at the predicted location in the faulty die to verify whether the predicated location included the fault.

Clause 8. The scan test fault analysis method of any of clauses 1-7, wherein the predicted location in the faulty die corresponds to at least one of a front end of line layer, a zeroth via layer, a first metal layer, a first via layer, a second metal layer, a second via layer, a third metal layer, and a combination of any via layers and metal layers above the third metal layer.

Clause 9. The scan test fault analysis method of any of clauses 1-8, further comprising:
training the artificial neural network on a plurality of diagnosis scan reports from a plurality of faulty test and validation dies having known fault locations before processing the plurality of features through the artificial neural network to provide the predicted location of the fault in the faulty die.

Clause 10. A scan test fault analysis system including at least one processor configured to:
select a plurality of features from a scan diagnosis report for a faulty die;
implement an artificial neural network; and
process the plurality of features through the artificial neural network to provide a predicted location of a fault in the faulty die.

Clause 11. The scan test fault analysis system of clause 10, wherein the artificial neural network comprises a first artificial neural network and a second artificial neural network, and wherein the plurality of features comprises a first plurality of features for the first artificial neural network and a second plurality of features for the second artificial neural network.

Clause 12. The scan test fault analysis system of clause 11, wherein the at least one processor is further configured to:
average a first prediction from the first artificial neural network with a second prediction from the second artificial neural network to provide the predicted location of the fault in the faulty die.

Clause 13. The scan test fault analysis system of any of clauses 10-12, wherein the plurality of features includes a total number of symptoms of the fault from the scan diagnosis report.

Clause 14. The scan test fault analysis system of any of clauses 10-12, wherein the plurality of features includes at least one feature selected from a group consisting of a total number of suspects for the location of the fault, a fault type, and a suspect layer for the fault location.

Clause 15. The scan test fault analysis system of clause 10, wherein the predicted location corresponds to at least one of a front end of line layer for the faulty die, a combination of a zeroth via layer and a first metal layer for the faulty die, a combination of a first via layer and a second metal layer for the faulty die, a combination of a second via layer and a third metal layer for the faulty die, and a combination of any via layers and metal layers above the third metal layer.

Clause 16. A scan test fault analysis method, comprising:
providing a plurality of faulty first dies, wherein each faulty first die in the plurality of faulty first dies has a known fault location;
performing a scan test on each faulty first die to provide a first scan diagnosis report for each faulty die;
selecting a plurality of features from each first scan diagnosis report to provide a selected first plurality of features for each faulty first die;
processing each selected first plurality of features through an artificial neural network to provide a predicted location of a fault in each faulty first die; and
training the artificial neural network to improve an accuracy of the predicated location based upon each faulty first die's known fault location to provide a trained artificial neural network.

Clause 17. The scan test fault analysis method of clause 16, wherein each selected first plurality of features includes a total number of symptoms of a fault from a corresponding one of the first scan diagnosis reports.

Clause 18. The scan test fault analysis method of clause 16, wherein each selected first plurality of features includes at least one feature selected from a group consisting of a total number of suspects for the fault location, a fault type, and a suspect layer for the fault location.

Clause 19. The scan test fault analysis method of clause 16, further comprising:
performing a scan test on a faulty second die using an automatic test equipment to provide a scan test result;
processing the scan test result in a diagnosis tool to provide a second scan diagnosis report;
selecting a plurality of features from the second scan diagnosis report to provide a second plurality of selected features; and
processing the second plurality of selected features through the trained artificial neural network to provide a predicted fault location for the faulty second die.

Clause 20. The scan test fault analysis method of clause 19, further comprising:
directing a physical fault analysis at the predicted fault location for the faulty second die.

It will be appreciated that many modifications, substitutions and variations can be made in and to the materials, apparatus, configurations and methods of use of the devices of the present disclosure without departing from the scope thereof. In light of this, the scope of the present disclosure should not be limited to that of the particular implementations illustrated and described herein, as they are merely by way of some examples thereof, but rather, should be fully commensurate with that of the claims appended hereafter and their functional equivalents.

We claim:

1. A scan test fault analysis method, comprising:
selecting a plurality of features from a scan diagnosis report for a faulty die; and
processing the plurality of features through an artificial neural network to provide a predicted location of a fault in the faulty die.

2. The scan test fault analysis method of claim 1, wherein selecting the plurality of features comprises selecting a first plurality of features for a first artificial neural network and selecting a second plurality of features for a second artificial neural network, and wherein processing the plurality of features through the artificial neural network comprises processing the first plurality of features through the first artificial neural network and processing the second plurality of features through the second artificial neural network.

3. The scan test fault analysis method of claim 2, further comprising:
averaging a first prediction from the first artificial neural network with a second prediction from the second artificial neural network to provide the predicted location of the fault in the faulty die.

4. The scan test fault analysis method of claim 1, further comprising:
performing a scan test on the faulty die using an automatic test equipment to provide a scan test result; and
processing the scan test result in a diagnosis tool to provide the scan diagnosis report.

5. The scan test fault analysis method of claim 4, wherein the plurality of features includes a total number of symptoms of the fault from the scan diagnosis report.

6. The scan test fault analysis method of claim 4, wherein the plurality of features includes at least one feature selected from a group consisting of a total number of suspects for a location of the fault, a fault type, and a suspect layer for the location of the fault.

7. The scan test fault analysis method of claim 1, further comprising:
directing a physical fault analysis at the predicted location in the faulty die to verify whether the predicated location included the fault.

8. The scan test fault analysis method of claim 1, wherein the predicted location in the faulty die corresponds to at least one of a front end of line layer, a zeroth via layer, a first metal layer, a first via layer, a second metal layer, a second via layer, a third metal layer, and a combination of any via layers and metal layers above the third metal layer.

9. The scan test fault analysis method of claim 1, further comprising:
training the artificial neural network on a plurality of diagnosis scan reports from a plurality of faulty test and validation dies having known fault locations before processing the plurality of features through the artificial neural network to provide the predicted location of the fault in the faulty die.

10. A scan test fault analysis system including at least one processor configured to:
select a plurality of features from a scan diagnosis report for a faulty die;
implement an artificial neural network; and
process the plurality of features through the artificial neural network to provide a predicted location of a fault in the faulty die.

11. The scan test fault analysis system of claim 10, wherein the artificial neural network comprises a first artificial neural network and a second artificial neural network, and wherein the plurality of features comprises a first plurality of features for the first artificial neural network and a second plurality of features for the second artificial neural network.

12. The scan test fault analysis system of claim 11, wherein the at least one processor is further configured to:
average a first prediction from the first artificial neural network with a second prediction from the second artificial neural network to provide the predicted location of the fault in the faulty die.

13. The scan test fault analysis system of claim 10, wherein the plurality of features includes a total number of symptoms of the fault from the scan diagnosis report.

14. The scan test fault analysis system of claim 10, wherein the plurality of features includes at least one feature selected from a group consisting of a total number of suspects for the location of the fault, a fault type, and a suspect layer for the fault location.

15. The scan test fault analysis system of claim 10, wherein the predicted location corresponds to at least one of a front end of line layer for the faulty die, a combination of a zeroth via layer and a first metal layer for the faulty die, a combination of a first via layer and a second metal layer for the faulty die, a combination of a second via layer and a third metal layer for the faulty die, and a combination of any via layers and metal layers above the third metal layer.

16. A scan test fault analysis method, comprising:
providing a plurality of faulty first dies, wherein each faulty first die in the plurality of faulty first dies has a known fault location;
performing a scan test on each faulty first die to provide a first scan diagnosis report for each faulty die;
selecting a plurality of features from each first scan diagnosis report to provide a selected first plurality of features for each faulty first die;
processing each selected first plurality of features through an artificial neural network to provide a predicted location of a fault in each faulty first die; and
training the artificial neural network to improve an accuracy of the predicated location based upon each faulty first die's known fault location to provide a trained artificial neural network.

17. The scan test fault analysis method of claim 16, wherein each selected first plurality of features includes a total number of symptoms of a fault from a corresponding one of the first scan diagnosis reports.

18. The scan test fault analysis method of claim 16, wherein each selected first plurality of features includes at least one feature selected from a group consisting of a total number of suspects for the fault location, a fault type, and a suspect layer for the fault location.

19. The scan test fault analysis method of claim 16, further comprising:
performing a scan test on a faulty second die using an automatic test equipment to provide a scan test result;
processing the scan test result in a diagnosis tool to provide a second scan diagnosis report;
selecting a plurality of features from the second scan diagnosis report to provide a second plurality of selected features; and
processing the second plurality of selected features through the trained artificial neural network to provide a predicted fault location for the faulty second die.

20. The scan test fault analysis method of claim 19, further comprising:
directing a physical fault analysis at the predicted fault location for the faulty second die.
